(19) United States
(12) Patent Application Publication
(10) Pub. No.: US 2023/0353123 A1
(43) Pub. Date: Nov. 2, 2023

(54) ACOUSTIC WAVE DEVICE

(71) Applicant: Murata Manufacturing Co., Ltd., Nagaokakyo-shi (JP)

(72) Inventor: Sho NAGATOMO, Nagaokakyo-shi (JP)

(21) Appl. No.: 18/213,287

(22) Filed: Jun. 23, 2023

Related U.S. Application Data
(63) Continuation of application No. PCT/JP2022/000362, filed on Jan. 7, 2022.

(30) Foreign Application Priority Data
Jan. 12, 2021 (JP) 2021-002899

(51) Int. Cl. H03H 9/25; H03H 9/02

(52) U.S. Cl. CPC H03H 9/25; H03H 9/02574; H03H 9/02818

(57) ABSTRACT

In an acoustic wave device, a piezoelectric layer is directly or indirectly laminated on a support substrate, an IDT electrode is provided on a first main surface of the piezoelectric layer, and F(x)=Ax²+Bx+C, where F(x) is equal to or less than about 10, when a thickness of a metal film of the IDT electrode normalized by a wavelength λ is defined as te, a thickness of the piezoelectric layer normalized by the wavelength λ is defined as tp, an equation of te/tp=x is satisfied, an average density obtained by normalizing a total mass of the metal film by the thickness te of the metal film is defined as y[g/cm³], and

A=1.0392y²+8.4182y−45.223;

B=0.0334y²−11.363y+28.984; and

C=19.

### CROSS REFERENCE TO RELATED APPLICATIONS

This application claims the benefit of priority to Japanese Patent Application No. 2021-002899 filed on Jan. 12, 2021 and is a Continuation Application of PCT Application No. PCT/JP2022/000362 filed on Jan. 7, 2022. The entire contents of each application are hereby incorporated herein by reference.

### BACKGROUND OF THE INVENTION

### 1. Field of the Invention

The present invention relates to an acoustic wave device in which a piezoelectric layer made of lithium tantalate is laminated directly or indirectly on a support substrate.

### 2. Description of the Related Art

In an acoustic wave device described in Japanese Unexamined Patent Application Publication No. 2018-092511, a piezoelectric layer made of LiTaO₃ is provided directly or indirectly on a support substrate. An IDT electrode is provided on the piezoelectric layer. In this acoustic wave device, an optimum cut angle θ of the piezoelectric layer is selected so that a spurious emission caused by a Rayleigh wave is minimized.

### SUMMARY OF THE INVENTION

In a piezoelectric composite substrate in which a thin piezoelectric layer made of LiTaO₃ is provided on a support substrate as in the acoustic wave device described in Japanese Unexamined Patent Application Publication No. 2018-092511, ripples caused by a Rayleigh wave occur on a lower frequency side than a frequency of main resonance. In Japanese Unexamined Patent Application Publication No. 2018-092511, in order to suppress the ripples, the cut angle of LiTaO₃ is optimized according to thicknesses of the piezoelectric layer and the IDT electrode that are normalized by a wavelength λ. Note that λ is a wavelength determined by an electrode finger pitch of the IDT electrode.

However, when a plurality of resonators is formed on the same piezoelectric composite substrate, the electrode finger pitch may be different between the resonators. In such a case, the normalized thickness of the piezoelectric layer and the normalized thickness of the IDT electrode are different for each electrode finger pitch. Thus, in some resonators, the cut angle may be different from the optimum cut angle, and in some cases, a spurious emission caused by a Rayleigh wave cannot be suppressed in all the resonators.

Preferred embodiments of the present invention provide acoustic wave devices each capable of effectively suppressing ripples caused by a Rayleigh wave.

An acoustic wave device according to a preferred embodiment of the present invention includes a piezoelectric composite substrate including a piezoelectric layer made of lithium tantalate, the piezoelectric layer including a first main surface and a second main surface that are opposed to each other, and a support substrate on which the piezoelectric layer is directly or indirectly laminated from a side of the first main surface, and a first IDT electrode provided on the first main surface of the piezoelectric layer, in which, when the first IDT electrode is made of a metal film, a wavelength determined by an electrode finger pitch of the first IDT electrode is defined as λ, a thickness of the metal film of the first IDT electrode normalized by the wavelength λ is defined as te, a thickness of the piezoelectric layer normalized by the wavelength λ is defined as tp, an equation of te/tp=x is satisfied, and an average density obtained by normalizing a total mass of the metal film by the thickness te of the metal film is defined as y [g/cm³], F(x) is equal to or less than about 10, F(x)=Ax²+Bx+C, A=1.0392y²+8.4182y−45.223, B=0.0334y²−11.363y+28.984, and C=19.

An acoustic wave device according to another preferred embodiment of the present invention includes a piezoelectric composite substrate including a piezoelectric layer made of lithium tantalate, the piezoelectric layer including a first main surface and a second main surface that are opposed to each other, and a support substrate on which the piezoelectric layer is directly or indirectly laminated from a side of the first main surface, a first IDT electrode provided on the first main surface of the piezoelectric layer, and a second IDT electrode provided on the second main surface of the piezoelectric layer, the second IDT electrode being opposed to the first IDT electrode with the piezoelectric layer interposed between the first IDT electrode and the second IDT electrode, in which, when the second IDT electrode is made of a metal film, a wavelength determined by an electrode finger pitch of the second IDT electrode is defined as A, a thickness of the metal film of the second IDT electrode normalized by the wavelength λ is defined as te, a thickness of the piezoelectric layer normalized by the wavelength λ is defined as tp, an equation of te/tp=x is satisfied, and an average density obtained by normalizing a total mass of the metal film by the thickness te of the metal film is defined as y [g/cm³], G(x) is equal to or less than about 10, G(x)=Ax²+Bx+C, A=0.0564y²+39.909y−29.023, B=0.1407y²−11.875y+5.4093, and C=19.

With the acoustic wave devices according to preferred embodiments of the present invention, ripples caused by a Rayleigh wave can be effectively reduced.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front cross-sectional view illustrating a main portion of an acoustic wave device according to a first preferred embodiment of the present invention.

FIG. 2 is a schematic plan view illustrating an electrode structure in the acoustic wave device according to the first preferred embodiment of the present invention.

FIG. 3 is a diagram illustrating a relationship between an Euler angle θ of LiTaO₃ and a coupling coefficient of a Rayleigh wave.

FIG. 4 is a diagram illustrating a relationship between an optimum angle (degrees) of an Euler angle θ and a thickness tp of LiTaO₃ normalized by a wavelength when an IDT electrode is made of Al in an acoustic wave device according to a known example.

FIG. 5 is a diagram illustrating a relationship between an optimum angle (degrees) of an Euler angle θ and a thickness tp of LiTaO₃ normalized by a wavelength when an IDT electrode is made of Cu in the acoustic wave device according to the known example.

FIG. 6 is a diagram illustrating a relationship between an optimum angle (degrees) of an Euler angle θ and a thickness tp of LiTaO₃ normalized by a wavelength when an IDT electrode is made of Cu in the acoustic wave device according to the first preferred embodiment of the present invention.

FIG. 7 is a diagram illustrating a relationship between an optimum angle (degrees) of an Euler angle θ and a thickness tp of LiTaO₃ normalized by a wavelength when an IDT electrode is made of Pt in the acoustic wave device of the known example.

FIG. 8 is a diagram illustrating a relationship between an optimum angle (degrees) of an Euler angle θ and a thickness tp of LiTaO₃ normalized by a wavelength when an IDT electrode is made of Pt in the acoustic wave device according to the first preferred embodiment of the present invention.

FIG. 9 is a diagram illustrating a relationship between a difference θ_{H}−θ_{L} (degrees) between optimum cut angles when a wavelength ratio thickness of the piezoelectric layer is 15% λ and 45% λ and a ratio te/tp when the IDT electrode is made of Cu in the acoustic wave device according to the known example and the acoustic wave device according to the first preferred embodiment of the present invention.

FIG. 10 is a diagram illustrating a relationship between a difference θ_{H}−θ_{L} (degrees) between optimum cut angles when a wavelength ratio thickness of the piezoelectric layer is 15% λ and 45% λ and a ratio te/tp when the IDT electrode is made of Pt in the acoustic wave device according to the known example and the acoustic wave device according to the first preferred embodiment of the present invention.

FIG. 11 is a diagram illustrating a relationship between a density of a metal film of a first IDT electrode and A and B in Equation (1).

FIG. 12 is a front cross-sectional view illustrating a main portion of an acoustic wave device according to a second preferred embodiment of the present invention.

FIG. 13 is a diagram illustrating a relationship between a density of metal of a second IDT electrode and A and B in Equation (4) in the acoustic wave device according to the second preferred embodiment of the present invention.

FIG. 14 is a front cross-sectional view illustrating a main portion of an acoustic wave device according to a third preferred embodiment of the present invention.

FIG. 15 is a front cross-sectional view illustrating a main portion of an acoustic wave device according to a fourth preferred embodiment of the present invention.

### DETAILED DESCRIPTION OF THE PREFERRED EMBODIMENTS

Hereinafter, specific preferred embodiments of the present invention will be described with reference to the drawings to clarify the present invention.

It should be noted that the preferred embodiments described in the present specification are merely examples, and partial replacement or combination of configurations is possible between different preferred embodiments.

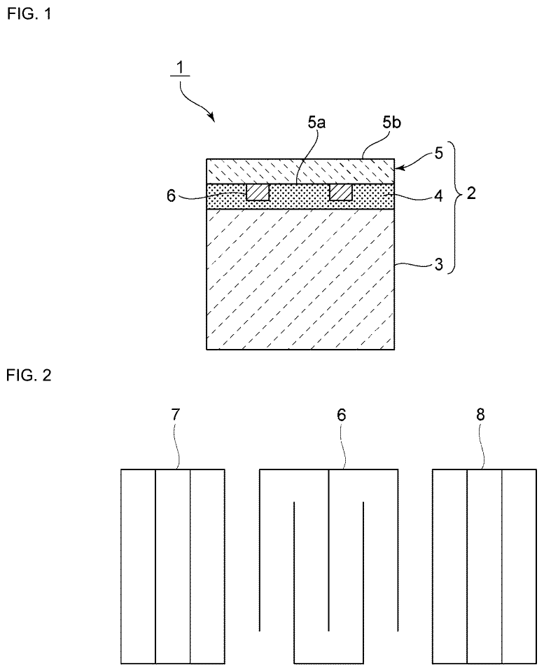

FIG. 1 is a front cross-sectional view illustrating a main portion of an acoustic wave device according to a first preferred embodiment of the present invention, and FIG. 2 is a schematic plan view illustrating an electrode structure of the acoustic wave device.

In an acoustic wave device 1, a piezoelectric composite substrate 2 includes a support substrate 3, a dielectric layer 4 laminated on the support substrate 3, and a piezoelectric layer 5. Note that the dielectric layer 4 does not need to be provided.

The support substrate 3 is made of an appropriate insulator or semiconductor. In the present preferred embodiment, the support substrate 3 is made of Si.

The dielectric layer 4 is made of an appropriate dielectric material, and is made of silicon oxide in the present preferred embodiment.

The piezoelectric layer 5 includes a first main surface 5a and a second main surface 5b that are opposed to each other. The piezoelectric layer 5 is laminated on the dielectric layer 4 from a side of the first main surface 5a. A first IDT electrode 6 is provided on the first main surface 5a of the piezoelectric layer 5.

The piezoelectric layer 5 is made of lithium tantalate. The lithium tantalate is preferably a rotated Y-cut X-propagation lithium tantalate, and a cut angle is more preferably equal to or more than about 40° and equal to or less than about 60°, for example.

Moreover, the first IDT electrode 6 is made of a metal film, and the metal film is made of an appropriate metal or alloy. The first IDT electrode 6 may include a laminated body made of the plurality of metal films.

As illustrated in FIG. 2, reflectors 7 and 8 are provided on both sides of the first IDT electrode 6 in an acoustic wave propagation direction. Thus, a one port type acoustic wave resonator is constituted.

Referring back to FIG. 1, the first IDT electrode 6 is provided on the first main surface 5a of the piezoelectric layer 5, and is embedded in the dielectric layer 4 except for a portion being in contact with the first main surface 5a. A wavelength determined by an electrode finger pitch in the first IDT electrode 6 is defined as A. A thickness of the metal film of the first IDT electrode 6 normalized by the wavelength is defined as te, and a thickness of the piezoelectric layer 5 normalized by the wavelength is defined as tp. Here, an equation of te/tp=x is satisfied. Note that te is a thickness of an electrode finger, and tp is a thickness of the piezoelectric layer 5 in an interdigitated region. When a density obtained by normalizing a total mass of the metal film of the first IDT electrode 6 by the thickness te of the metal film is defined as an average density y[g/cm³], F(x) given by the following Equation (1) is equal to or less than 10.

F(x)=Ax²+Bx+C Equation (1)

Note that in Equation (1), A and B are represented by the following Equations (2) and (3), and an equation of C=19 is satisfied.

A=1.0392y²+8.4182y−45.223 Equation (2)

B=0.0334y²−11.363y+28.984 Equation (3)

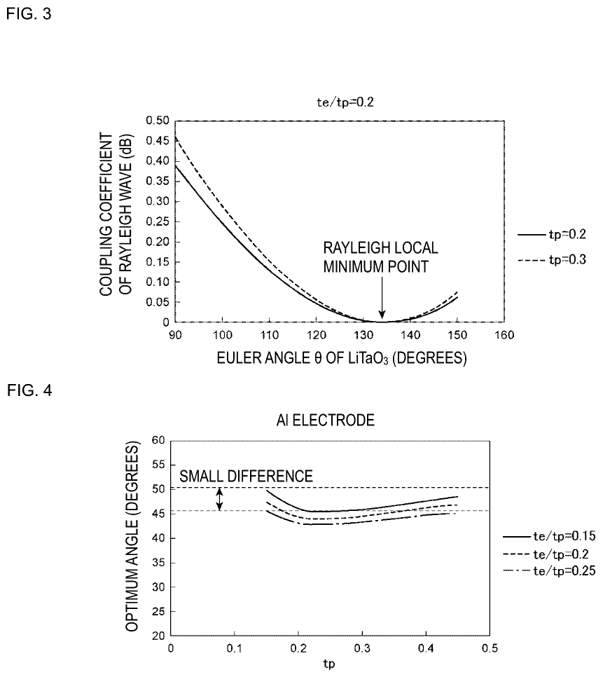

In the acoustic wave device 1, since F(x) described above is equal to or less than 10, ripples caused by a Rayleigh wave can be effectively suppressed. This will be described in more detail with reference to FIG. 3 to FIG. 11.

FIG. 3 is a diagram illustrating a relationship between an Euler angle θ of LiTaO₃ and a coupling coefficient of a Rayleigh wave in an acoustic wave device according to a known example. Note that FIG. 3 indicates results obtained when the IDT electrode is made of Al. In FIG. 3, the solid line indicates the result in the case of tp=0.2 and the broken line indicates the result in the case of tp=0.3. In both the cases of tp=0.2 and tp=0.3, the Euler angle θ where a coupling coefficient of a Rayleigh wave is minimized hardly changes.

In addition, FIG. 4 is a diagram illustrating a relationship between an optimum angle of the Euler angle θ and tp in the case of te/tp=0.15, 0.2, or 0.25. It is apparent from FIG. 4 that even when te/tp is changed to 0.15, 0.2 or 0.25, the change of the optimum angle is small. Thus, in the case where the IDT electrode is made of Al, even when resonators having different pitches are formed on the same piezoelectric composite substrate, the Euler angle θ can be easily set to an optimum angle, and the Rayleigh wave can be suppressed in any case in the resonators having different electrode finger pitches.

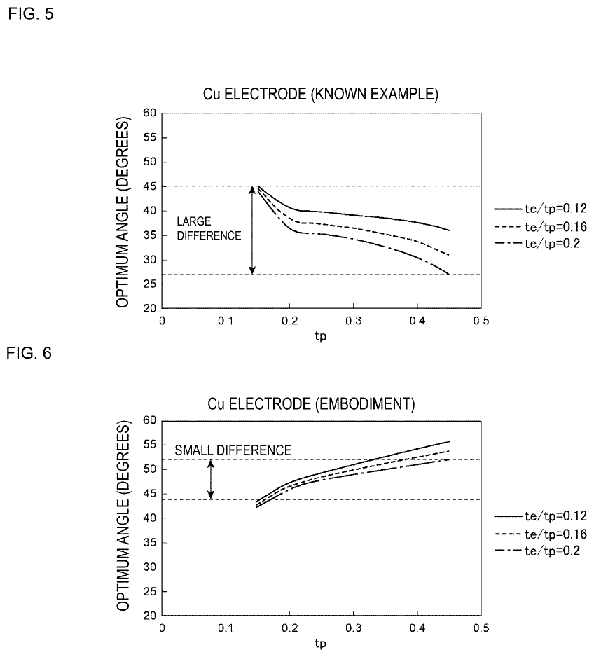

However, in the acoustic wave device according to the known example, in the case where the IDT electrode is made of Cu, as illustrated in FIG. 5, when te/tp changes to 0.12, 0.16, or 0.2, the optimum angle of the Euler angle θ largely changes. Thus, in the case where the plurality of resonators is formed on the same piezoelectric composite substrate, when the electrode finger pitches of the plurality of resonators are different from each other, in some resonators, the Euler angle deviates from the optimum angle of the Euler angle θ. This causes the presence of a resonator that cannot suppress ripples caused by the Rayleigh wave.

On the other hand, FIG. 6 is a diagram illustrating a relationship between an optimum angle of the Euler angle θ and tp when the first IDT electrode 6 according to the first preferred embodiment of the present invention is made of Cu. It is apparent from FIG. 6 that even when te/tp changes to 0.12, 0.16, or 0.2, the optimum angle of the Euler angle θ hardly changes. Thus, according to the acoustic wave device 1 of the present preferred embodiment, even when the plurality of acoustic wave resonators having different electrode finger pitches is formed on the same piezoelectric composite substrate 2, ripples caused by the Rayleigh wave can be effectively suppressed. This is because F(x) is equal to or less than 10 in the present preferred embodiment, as will be described later.

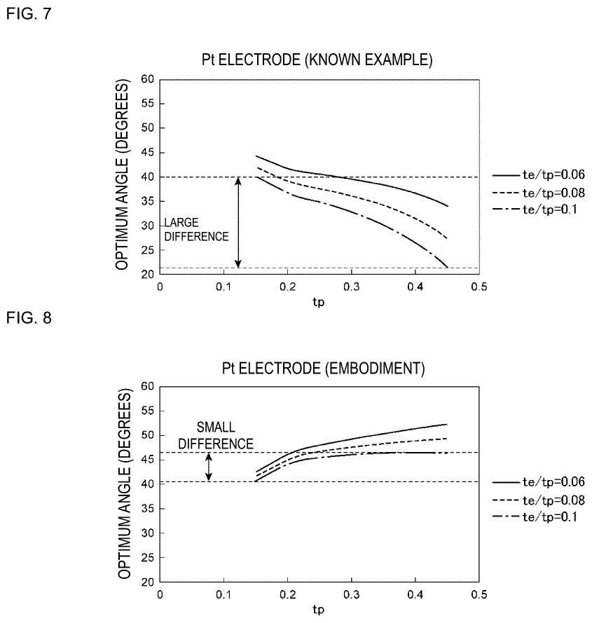

FIG. 7 is a diagram illustrating a relationship between an optimum angle of the Euler angle θ and tp when the IDT electrode is made of Pt in the acoustic wave device according to the known example. It is apparent from FIG. 7 that also in the case where the IDT electrode is made of Pt, when te/tp changes to 0.06, 0.08, or 0.1, the optimum angle of the Euler angle θ largely changes. Thus, as in the case of Cu, when the plurality of acoustic wave resonators is formed on the same piezoelectric composite substrate, some acoustic wave resonators cannot sufficiently suppress the ripples caused by the Rayleigh wave.

FIG. 8 is a diagram illustrating a relationship between an optimum angle of the Euler angle θ and tp when the IDT electrode is made of Pt in the acoustic wave device according to the first preferred embodiment of the present invention. It is apparent from FIG. 8 that the difference in the optimum angle of the Euler angle θ is small in any case where te/tp is 0.06, 0.08, or 0.1. Thus, also in the case where the IDT electrode is made of Pt, as in the case where the IDT electrode is made of Cu, the ripples caused by the Rayleigh wave can be effectively suppressed according to the present preferred embodiment.

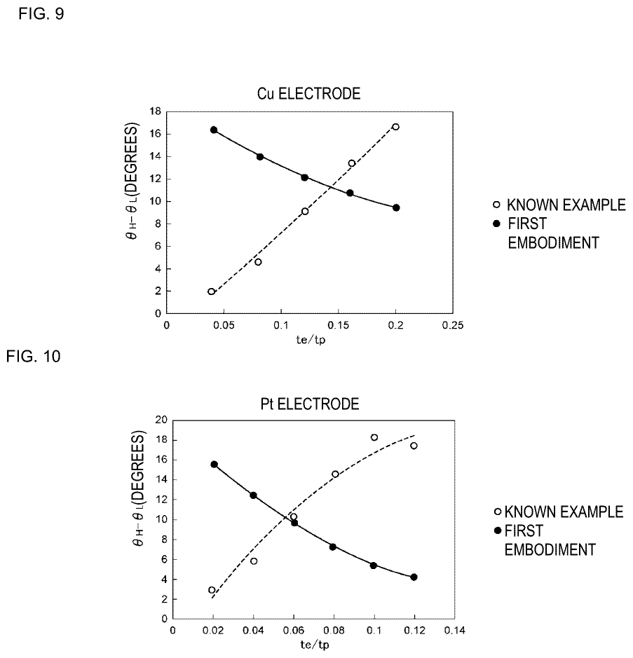

FIG. 9 is a diagram illustrating a relationship between a difference θ_{H}−θ_{L} between optimum cut angles when a wavelength ratio thickness of the piezoelectric layer is 15% λ at the minimum and 45% λ at the maximum and te/tp when the IDT electrode is made of Cu. The solid line indicates a result of the first preferred embodiment, and the broken line indicates a result of the acoustic wave device according to the known example.

Additionally, FIG. 10 is a diagram illustrating a relationship between θ_{H}−θ_{L} and te/tp when the IDT electrode is made of Pt. The solid line indicates a result of the first preferred embodiment and the broken line indicates a result of the acoustic wave device according to the known example.

It is apparent from FIG. 9 and FIG. 10 that when the metal film of the IDT electrode is as heavy as Cu or Pt, θ_{H}−θ_{L} decreases as te/tp increases, as opposed to the acoustic wave device according to the known example. On the other hand, in the acoustic wave device according to the known example, the difference θ_{H}−θ_{L} between the optimum cut angles increases as te/tp increases.

Thus, when a metal film having a high density such as Cu, Pt or the like is used, an acoustic wave can be slowed down, and a change in response caused by the Rayleigh wave is less likely to occur with respect to a change in tp.

As a result, in order to obtain an acoustic wave device in which the ripples caused by the Rayleigh wave are less likely to occur due to the change in tp, it is desirable that a difference between optimum cut angles at an upper limit and a lower limit of tp, that is, θ_{H}−θ_{L}, be small. In addition, it is apparent from FIG. 9 and FIG. 10 that this value is a function of te/tp when an electrode density is fixed. The present inventors have discovered that this function can be expressed by the following Equation (1) when te/tp=x is satisfied.

Thus, the metal film of the first IDT electrode 6 preferably includes a metal layer made of metal having a higher density than that of Al. More preferably, a metal layer having a higher density than that of Al is a main metal layer of the metal film.

Note that the coefficients A and B in the Equation (1) are represented by the above-described Equations (2) and (3), and C is 19.

Note that in the case where the first IDT electrode 6 includes n (n is a natural number) laminated films, when a density of an i-th layer is pi and a volume thereof is ti, y is represented by an average density of the electrode layers, that is, y=Σ(ti×ρi)/Σ(ti). Here, Σ(ti×ρi) is a total mass. Note that ti is a volume, but may be replaced with a thickness when a cross section of the electrode finger has a rectangular or substantially rectangular shape.

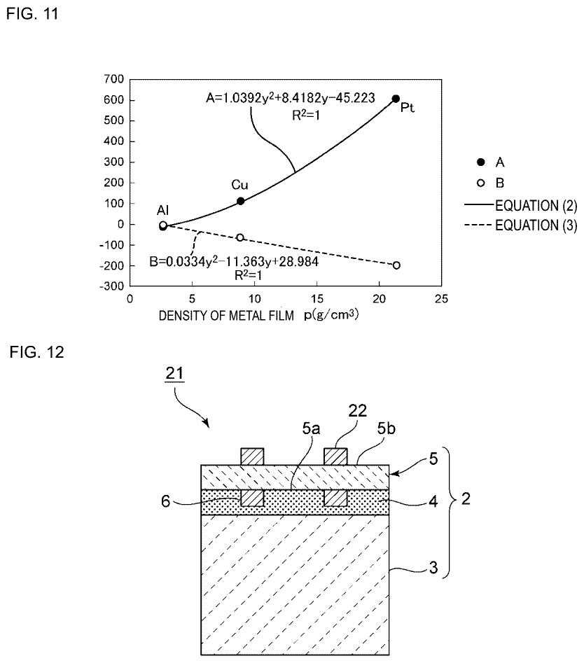

FIG. 11 is a diagram for explaining the coefficients A and B described above in the acoustic wave device according to the preferred embodiment described above. In any case where the metal film of the IDT electrode is Al, Cu, or Pt, it can be seen that A and B can be represented by Equations (2) and (3) described above. Note that y in FIG. 11 is a value of a density of the metal film in FIG. 11. Thus, in a preferred embodiment of the present invention, with te/tp and the density of the metal of the IDT electrode such that F(x) represented by Equation (1) is within a certain range or less, the ripples caused by the Rayleigh wave can be effectively suppressed. In a preferred embodiment of the present invention, F(x) is equal to or less than about 10, and more preferably equal to or less than about 5. As a result, ripples caused by the Rayleigh wave can be effectively suppressed regardless of the type and density of the metal film of the IDT electrode.

This is considered to be because a surface of the piezoelectric layer including the electrode is the first main surface, that is, on the support substrate side, so that a relationship between an Euler angle θ dependency of the coupling coefficient of the Rayleigh wave and a mass of the metal film of the IDT electrode is opposite to a relationship in the acoustic wave device according to the known example.

FIG. 12 is a front cross-sectional view illustrating a main portion of an acoustic wave device according to a second preferred embodiment of the present invention. In an acoustic wave device 21, the piezoelectric composite substrate 2 includes the support substrate 3, the dielectric layer 4, and the piezoelectric layer 5, as in the case of FIG. 1. However, in the acoustic wave device 21, not only is the first IDT electrode 6 provided on the first main surface 5a of the piezoelectric layer 5, but also a second IDT electrode 22 is provided on the second main surface 5b. The second IDT electrode 22 is provided so as to overlap the first IDT electrode 6 with the piezoelectric layer 5 interposed therebetween. Further, a metal film of the second IDT electrode 22 is similar to that of the first IDT electrode 6. However, the metal film of the second IDT electrode 22 may be different from the metal film of the first IDT electrode 6.

Also in the acoustic wave device 21 according to the second preferred embodiment, when G(x) represented by the following Equation (4) is equal to or less than 10, and preferably equal to or less than 5, ripples caused by the Rayleigh wave can be effectively suppressed. Note that the following Equations (4) to (6) are equations defined for the second IDT electrode 22. Thus, the following Equations (4) to (6) are equations obtained when a wavelength determined by an electrode finger pitch of the second IDT electrode 22 is defined as λ, a thickness of the metal film of the second IDT electrode 22 normalized by the wavelength is defined as te, a thickness of the piezoelectric layer 5 normalized by the wavelength is defined as tp, an equation of te/tp=x is satisfied, and an average density obtained by normalizing a total mass of the metal film of the second IDT electrode 22 by the thickness te of the metal film is defined as y[g/m³].

G(x)=Ax²+Bx+C Equation (4)

Note that in Equation (4), A and B are represented by the following Equations (5) and (6), and an equation of C=19 is satisfied.

A=0.0564y²+39.909y−29.023 Equation (5)

B=0.1407y²−11.875y+5.4093 Equation (6)

In this case, a potential of the second IDT electrode 22 may have a freely selected phase.

However, when an SH wave is excited, it is preferable that each of electrode fingers of the second IDT electrode 22 have the same phase as that of the corresponding one of the electrode fingers of the first IDT electrode 6, the corresponding one being opposed to the electrode finger of the second IDT electrode 22. In the second preferred embodiment, a mass added by the first IDT electrode 6 is preferably larger than a mass added by the second IDT electrode 22.

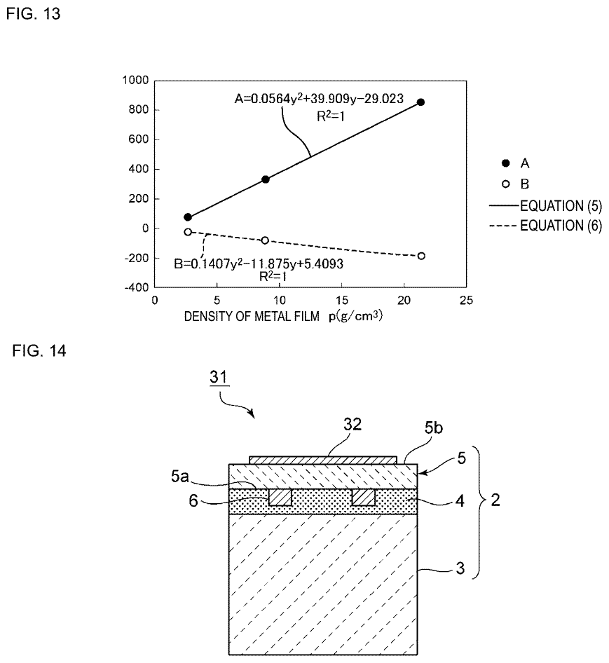

FIG. 13 illustrates a relationship between a density of the second IDT electrode 22 and a coefficient A or B in Equation (4) when the mass of the first IDT electrode 6 is equal or substantially equal to the mass of the second IDT electrode 22. In FIG. 13, the solid line represents Equation (5) and the broken line represents Equation (6). Note that y in FIG. 13 is a value of a density of the metal film in FIG. 13.

A=0.0564y²+39.909y−29.023 Equation (5)

B=0.1407y²−11.875y+5.4093 Equation (6)

In the acoustic wave device 21 according to the second preferred embodiment, when G(x) is equal to or less than about 10, and preferably equal to or less than about 5, the ripples caused by the Rayleigh wave can be effectively suppressed.

FIG. 14 is a front cross-sectional view illustrating a main portion of an acoustic wave device according to a third preferred embodiment of the present invention. In an acoustic wave device 31, a conductive film 32 is provided on the second main surface 5b of the piezoelectric layer 5. The other configurations of the acoustic wave device 31 are similar to those of the acoustic wave device 1 illustrated in FIG. 1. In this manner, the conductive film 32 may be provided on the second main surface 5b side. In this case, the conductive film 32 may be provided as a floating electrode so as to face at least a portion of the first IDT electrode 6. In this case, capacitance is generated through the piezoelectric layer 5.

Alternatively, the conductive film 32 described above and the dielectric layer 4 may be provided only in a region that is opposed to the tips of the electrode fingers of the first IDT electrode 6. In this case, an acoustic wave device utilizing a piston mode can be provided by lowering an acoustic velocity in a region of the tips of the electrode fingers.

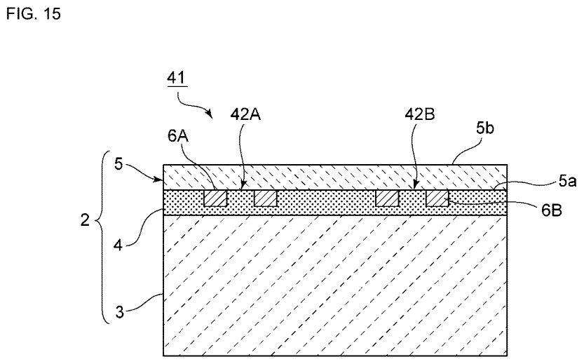

FIG. 15 is a front cross-sectional view illustrating a main portion of an acoustic wave device according to a fourth preferred embodiment of the present invention. In the acoustic wave device 41, a first acoustic wave resonator 42A and a second acoustic wave resonator 42B are provided in the piezoelectric composite substrate 2. An electrode finger pitch of an IDT electrode 6A of the first acoustic wave resonator 42A is different from an electrode finger pitch of an IDT electrode 6B of the second acoustic wave resonator 42B. That is, resonant frequencies of the first and second acoustic wave resonators 42A and 42B are different from each other. Even in such a case, as described above, since the optimum cut angles of LiTaO₃ of the piezoelectric layer 5 are close to each other, ripples caused by the Rayleigh wave can be effectively suppressed in both the first and second acoustic wave resonators 42A and 42B.

Note that in an acoustic wave device according to a preferred embodiment of the present invention, three or more acoustic wave resonators may be provided in the same piezoelectric composite substrate. Even in this case, the ripples caused by the Rayleigh wave in each acoustic wave resonator can be efficiently suppressed by setting F(x) to be equal to or less than about 10 according to a preferred embodiment of the present invention.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric composite substrate including:
a piezoelectric layer made of lithium tantalate, the piezoelectric layer including a first main surface and a second main surface that are opposed to each other; and
a support substrate on which the piezoelectric layer is directly or indirectly laminated from a side of the first main surface; and
an IDT electrode provided on the first main surface of the piezoelectric layer; wherein
when the IDT electrode is made of a metal film, a wavelength determined by an electrode finger pitch of the IDT electrode is defined as λ, a thickness of the metal film of the IDT electrode normalized by the wavelength λ is defined as te, a thickness of the piezoelectric layer normalized by the wavelength λ is defined as tp, an equation of te/tp=x is satisfied, and an average density obtained by normalizing a total mass of the metal film by the thickness te of the metal film is defined as y [g/cm³], F(x) is equal to or less than about 10;
F(x)=Ax²+Bx+C;
A=1.0392y²+8.4182y−45.223;
B=0.0334y²−11.363y+28.984; and
C=19.

2. The acoustic wave device according to claim 1, wherein F(x) is equal to or less than about 5.

3. The acoustic wave device according to claim 1, wherein a conductive film is provided on the second main surface of the piezoelectric layer.

4. The acoustic wave device according to claim 1, wherein the metal film of the IDT electrode includes a metal layer made of metal having a higher density than a density of Al.

5. The acoustic wave device according to claim 4, wherein the metal layer having the higher density than the density of the Al is a main metal layer of the metal film.

6. The acoustic wave device according to claim 1, wherein
a dielectric layer is provided between the support substrate and the first main surface of the piezoelectric layer; and
the IDT electrode is in contact with the first main surface of the piezoelectric layer and is embedded in the dielectric layer.

7. The acoustic wave device according to claim 6, wherein the dielectric layer includes a material made of silicon oxide.

8. The acoustic wave device according to claim 1, wherein
two of the IDT electrodes are provided on the first main surface of the piezoelectric layer; and
an electrode finger pitch of one of the two of the IDT electrodes is different from an electrode finger pitch of another of the two of the IDT electrodes.

9. The acoustic wave device according to claim 1, wherein the piezoelectric layer is made of rotated Y-cut X-propagation lithium tantalate and has a cut angle within a range being equal to or more than about 40° and equal to or less than about 60°.

10. The acoustic wave device according to claim 1, further comprising reflectors respectively provided on opposite sides of the IDT electrode.

11. The acoustic wave device according to claim 1, wherein the acoustic wave device is a one port acoustic wave resonator.

12. An acoustic wave device comprising:
a piezoelectric composite substrate including:
a piezoelectric layer made of lithium tantalate, the piezoelectric layer including a first main surface and a second main surface that are opposed to each other; and
a support substrate on which the piezoelectric layer is directly or indirectly laminated from a side of the first main surface;
a first IDT electrode provided on the first main surface of the piezoelectric layer; and
a second IDT electrode provided on the second main surface of the piezoelectric layer, the second IDT electrode being opposed to the first IDT electrode with the piezoelectric layer interposed between the first IDT electrode and the second IDT electrode; wherein
when the second IDT electrode is made of a metal film, a wavelength determined by an electrode finger pitch of the second IDT electrode is defined as A, a thickness of the metal film of the second IDT electrode normalized by the wavelength λ is defined as te, a thickness of the piezoelectric layer normalized by the wavelength λ is defined as tp, an equation of te/tp=x is satisfied, and an average density obtained by normalizing a total mass of the metal film by the thickness te of the metal film is defined as y [g/cm³], G(x) is equal to or less than about 10;
G(x)=Ax²+Bx+C;
A=0.0564y²+39.909y−29.023;
B=0.1407y²−11.875y+5.4093; and
C=19.

13. The acoustic wave device according to claim 12, wherein the metal film of the first IDT electrode includes a metal layer made of metal having a higher density than a density of Al.

14. The acoustic wave device according to claim 13, wherein the metal layer having the higher density than the density of the Al is a main metal layer of the metal film.

15. The acoustic wave device according to claim 12, wherein
a dielectric layer is provided between the support substrate and the first main surface of the piezoelectric layer; and
the first IDT electrode is in contact with the first main surface of the piezoelectric layer and is embedded in the dielectric layer.

16. The acoustic wave device according to claim 15, wherein the dielectric layer includes a material made of silicon oxide.

17. The acoustic wave device according to claim 12, wherein
two of the first IDT electrodes are provided on the first main surface of the piezoelectric layer; and
an electrode finger pitch of one of the two of the first IDT electrodes is different from an electrode finger pitch of another of the two of the first IDT electrodes.

18. The acoustic wave device according to claim 12, wherein the piezoelectric layer is made of rotated Y-cut X-propagation lithium tantalate and has a cut angle within a range being equal to or more than about 40° and equal to or less than about 60°.

19. The acoustic wave device according to claim 12, further comprising reflectors respectively provided on opposite sides of the first IDT electrode.

20. The acoustic wave device according to claim 12, wherein the acoustic wave device is a one port acoustic wave resonator.
